(19) United States
(12) Patent Application Publication
(10) Pub. No.: US 2002/0177306 A1
(43) Pub. Date: Nov. 28, 2002

(54) Method to place a thermal interface when manufacturing an integrated circuit

(76) Inventor: Vadim Gektin, San Jose, CA (US)

Correspondence Address: HAMILTON & TERRILE, LLP, P.O. BOX 203518, AUSTIN, TX, 78759, US

(21) Appl. No.: 09/865,903

(22) Filed: May 25, 2001

(51) Int. Cl. H01L 21/44; H01L 21/48; H01L 21/50; H01L 23/02

(52) U.S. Cl. 438/678; 438/122; 257/678

(57) ABSTRACT

In accordance with the present invention, a method is described which facilitates placement of a thermal interface on a thermal lid. The thermal lid, which facilitates cooling, is placed on the silicon layer after the silicon layer has been bonded to the substrate layer. The thermal interface can be organic. In an embodiment the thermal interface is metallic. In another embodiment the thermal interface is an alloy. Placing the thermal interface on the lid eliminates a step from the manufacturing process of the package. In another embodiment an inorganic thermal interface is placed on the silicon layer prior to bonding with the substrate layer.

The method also teaches using a thermal interface with a melting point above a specified temperature. In a preferred embodiment a melting point of greater than 62° C. is described.

### BACKGROUND OF THE INVENTION

1. Field of the Invention

The present invention relates to manufacturing integrated circuits. More specifically, the invention relates to using a thermal interface to promote even cooling of the silicon layer of an integrated circuit.

2. Description of the Related Art

Digital circuits, no matter how complex, are composed of a small group of identical building blocks. These blocks can be gates or special circuits or other structures for which gates are less suitable. But the majority of digital circuits are composed of gates or combinations of gates.

A microprocessor is a central processing unit of a computer or other device using thousands (or millions) of gates, flip-flops and memory cells. Flip-flops and memory cells are modified versions of basic logic gates. Gates are combinations of high-speed electronic switches.

It is known to manufacture an integrated circuit using conductors separated by a semiconductor. Circuits are fabricated on a semiconductor by selectively altering the conductivity of the semiconductor material. Various conductivity levels correspond to elements of a transistor, diode, resistor, or small capacitor. Individual components such as transistors, diodes, resistors, and small capacitors are formed on small chips of silicon. These individual components are interconnected by wiring patterns (typically aluminum, copper or gold).

An integrated circuit is then included in a larger structure, known as integrated circuit package, that provides electrical connections between the integrated circuit and the next level assembly. The integrated circuit package also serves structural functions. Integrated circuit packages are then mounted on printed (or wired) circuit boards which are used to assemble electronic systems such as personal computers and other data processing equipment.

It is known to manufacture an integrated circuit package using a layer of silicon and a layer of a substrate. Typically, a substrate can be an organic material or a ceramic. Heat is applied during the manufacturing process to bond the silicon layer to the substrate layer. After bonding the silicon layer to the substrate layer a lid (sometimes is referred to as a thermal lid) is attached to facilitate the cooling process. The lid also provides structural stability to the package.

The substrate layer can be ceramic or another material with the necessary electrical conducting properties. Heat is applied during the manufacturing process to bond the silicon layer to the substrate layer. Uneven cooling of the silicon and substrate layers (sometimes referred to as the “package”) produces defects in the package. Uniform cooling minimizes the number of manufacturing defects in the package.

The thermal lid serves to conduct heat from the integrated circuit package to the environment and thus facilitates even cooling. The lid is typically formed from a metal due to the thermal conductivity of metals. However, the thermal lid is typically formed from a metal. Typically, neither the thermal lid nor the silicon surface are sufficiently flat to provide an efficient heat exchange interface. Thus, imperfections in the surface of the thermal lid and the surface of the silicon prevent complete surface contact between the surface of the silicon and the surface of the thermal lid. The incomplete surface contact is an impediment to heat transfer which in turn causes imperfections on the silicon wafer.

To facilitate surface contact between the thermal lid and the silicon surface a thermal interface is employed. The thermal interface is organic and is not a solid. The thermal interface (sometimes referred to as a thermal paste) can be applied to the surface of the silicon before the thermal lid is attached. The thermal paste is not a solid and can conform to imperfections in the surface of the silicon. Similarly, the thermal paste can conform to imperfections in the surface of the thermal lid. Thus, using a thermal paste increases the surface contact between the silicon and the thermal lid and promotes heat transfer.

It is known to employ a thermal interface which is organic. Organic thermal interfaces are available which can be applied to the silicon layer. Due to the difficulty of applying a metallic thermal interface to the silicon layer, metallic thermal interfaces are not used. Similarly, alloys exist which have superior thermal conductive qualities to metals. For example, solder is a mixture of lead and tin. Solder has superior heat conductive properties to many metals. An alloy can also be used as a thermal interface. Applying an alloy directly to a thermal lid avoids the problems of applying the alloy to the silicon surface.

FIG. 1A depicts placing organic thermal interface 120 on silicon layer 130. FIG. 1A depicts silicon layer 130 and substrate layer 140 which combine to form package 150. FIG. 1B depicts placement of thermal lid 110 on silicon layer 130. As shown, substrate layer 140 is bonded to the opposing side of silicon layer 130 from organic thermal interface 121 and thermal lid 100.

FIG. 2 depicts the logical steps of placing organic thermal interface 120 on the silicon layer. As shown in FIG. 2, the method begins with start 210. From start 210 the logical steps include providing substrate layer 230, providing silicon layer 220 and providing thermal lid 240. After providing silicon layer 220 and providing substrate layer 230 the silicon layer and substrate layer are bonded 250. Provide thermal lid 240 is shown occurring prior to bonding the silicon layer to the substrate layer 250 but in an implementation can occur later. After providing thermal lid 240 the organic thermal interface is placed on the silicon layer 260. After the organic thermal interface is placed on the silicon layer 260 the thermal lid is placed on the silicon layer 270. After the thermal lid and organic thermal interface are placed on the silicon layer 270, the process ends 280.

As shown in FIG. 1B and FIG. 2, replacing the thermal interface on the surface of the silicon is a step in the manufacturing process. Each step in the manufacturing process increases the cost of manufacture of the integrated circuit package and introduces an opportunity for error. Eliminating steps from the manufacturing process reduces the manufacturing cost.

In addition, each step in the manufacturing process which can be eliminated also reduces opportunity for error. In the instant example, error can be introduced by an excess of thermal interface material or my uneven application of thermal interface material. Either condition introduces an error into the manufacturing process which can cause defects in the finished product. Eliminating this step from the process reduces the possibility of error. Reducing error reduces rejected components and quality control time and thus reduces cost.

What is needed is a method of attaching a thermally conductive lid to the silicon layer after bonding without the added step of placing the thermal interface on the silicon layer. An embodiment could include applying an inorganic conductive layer directly to the silicon layer before the thermal lid is attached.

### SUMMARY OF THE INVENTION

In accordance with the present invention, a method is described which facilitates placement of a thermal interface on a thermal lid. The thermal lid, which facilitates cooling, is placed on the silicon layer after the silicon layer has been bonded to the substrate layer. The thermal interface can be organic. In an embodiment the thermal interface is metallic. In another embodiment the thermal interface is an alloy. Placing the thermal interface on the lid eliminates a step from the manufacturing process of the package. In another embodiment an inorganic thermal interface is placed on the silicon layer prior to bonding with the substrate layer.

The method also teaches using a thermal interface with a particular melting point, or a melting point above a specified temperature. In one embodiment a thermal interface with a melting point greater than 16° C. is used. In a preferred embodiment a melting point of greater than 62 C is specified. Typically, the melting point of the thermal interface used will be greater than 105° C.

The foregoing is a summary and this contains, by necessity, simplifications, generalizations and omissions of detail; consequently, those skilled in the art will appreciate that the summary is illustrative only and is not intended to be in any way limiting.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1A depicts the related art of placing an organic thermal interface on a silicon layer after the silicon layer is bonded to the substrate. FIG. 1B depicts another step in the related art, placing the thermal lid on organic thermal interface.

FIG. 2 depicts a process flow diagram depicting logical steps of the related art. Specifically, FIG. 2 depicts the logical steps of the related art of placing an organic thermal interface on the silicon layer before the thermal lid is placed.

FIG. 3A depicts placing a thermal interface on the thermal lid. FIG. 3B depicts another step in the manufacturing process, placing the thermal lid (with thermal interface) on the silicon layer.

FIG. 4 depicts a process flow diagram depicting logical steps of an embodiment. Specifically, FIG. 4 depicts the logical steps of placing a thermal interface on the thermal lid and placing the thermal lid (with thermal interface) on the silicon layer.

FIG. 5 depicts another embodiment. Specifically FIG. 5A depicts placing an inorganic thermal interface on the thermal lid. FIG. 5B depicts placing the thermal lid (with inorganic thermal interface) on the silicon layer.

FIG. 6 depicts a process flow diagram depicting logical steps of an implementation. Specifically, FIG. 6 shows the logical steps of placing an inorganic thermal interface on the thermal lid and placing the thermal lid (with inorganic thermal interface) on the silicon layer.

FIG. 7 is a block diagram of a computer system. The computer system incorporates various components (central processing unit, memory, etc.) which are integrated circuits which may be manufactured fabricated using the method taught.

### DETAILED DESCRIPTION

The following sets forth a detailed description of a mode for carrying out the invention. The description is intended to be illustrative of the invention and should not be taken to be limiting. A method is taught of placing a thermal interface on a thermal lid during manufacture of an integrated circuit package. Alternately, the thermal interface can be placed on the surface of the silicon. In one embodiment, the thermal interface has a melting point above 16° C. In another embodiment, the thermal interface has a melting point above 62° C. In a preferred embodiment, the thermal interface has a melting point above 16° C. but below the melting point of package components such as solder. The melting point of package components is approximately 160° C. Using a material with a melting point above 16° C. eliminates materials with melting points substantially below room temperature. Similarly, using a material with a melting point below 160° C. eliminates materials with melting points above the melting point of package components such as silicon.

A material which is suitable for a thermal interface is manufactured by Thermagon of Cleveland, Ohio. This specific material, referred to as T-lma-60 has suitable thermal conductive properties and can be used as a thermal interface when applied to a silicon layer after the layer is bonded to a substrate. T-lma-60 can have more than one layer and is a thermal conductive structure phase change material. T-lma-60 changes phase from solid to liquid at approximately 60° C. A thermal interface, such as T-lma-60 or other, can have a plurality of layers. For example, a thermal interface such as T-lma-60 can have three layers, one of which can be a metallic central layer. According to one embodiment, this material can also be applied to a thermal lid. The silicon lid and thermal interface can be placed on the silicon surface after the silicon is bonded to the substrate.

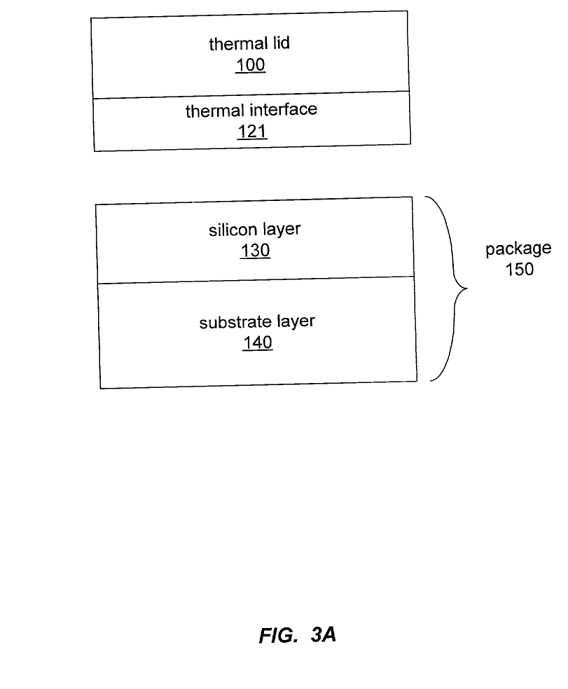

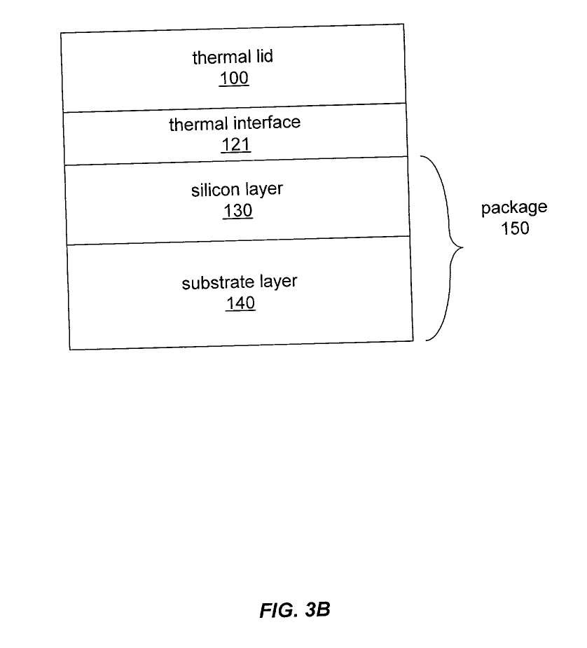

FIG. 3A depicts placing a thermal interface 121 on the thermal lid 100. Thermal interface 120 can be organic or inorganic. In an embodiment, thermal interface 120 is metallic. In another embodiment, thermal interface 121 is an alloy, for example solder which is a mixture of lead and tin. In another embodiment thermal interface 120 can have layers. The layers can be organic, inorganic or both organic and inorganic. FIG. 3A depicts silicon layer 130 and substrate layer 140 which combine to form package 150. FIG. 3B depicts placement of thermal lid 110 and thermal interface 121 on silicon layer 130. Substrate layer 140 is bonded to the opposing side of silicon layer 130 from thermal interface 121 and thermal lid 100.

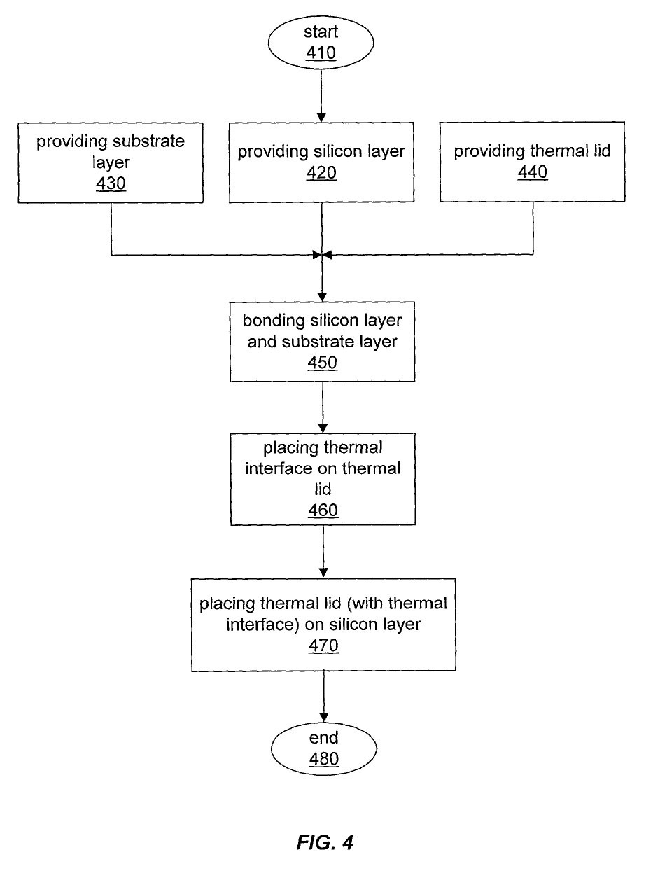

FIG. 4 depicts the logical steps of placing thermal interface 121 on the thermal lid 100. As shown in FIG. 4, the method begins with start 410. From start 410 the logical steps include provide substrate layer 430, provide silicon layer 420 and provide thermal lid 440. After providing silicon layer 420 and providing substrate layer 430 the silicon layer and substrate layer are bonded 450. Provide thermal lid 440 is shown occurring prior to bonding the silicon layer to the substrate layer 450 but in an implementation can occur later. After providing thermal lid 440 the thermal interface is placed on the lid 460. After the thermal interface is placed on the thermal lid 460 the thermal lid is placed on the silicon layer 460. After the thermal lid and thermal interface are placed on the silicon layer 470, the process ends 480.

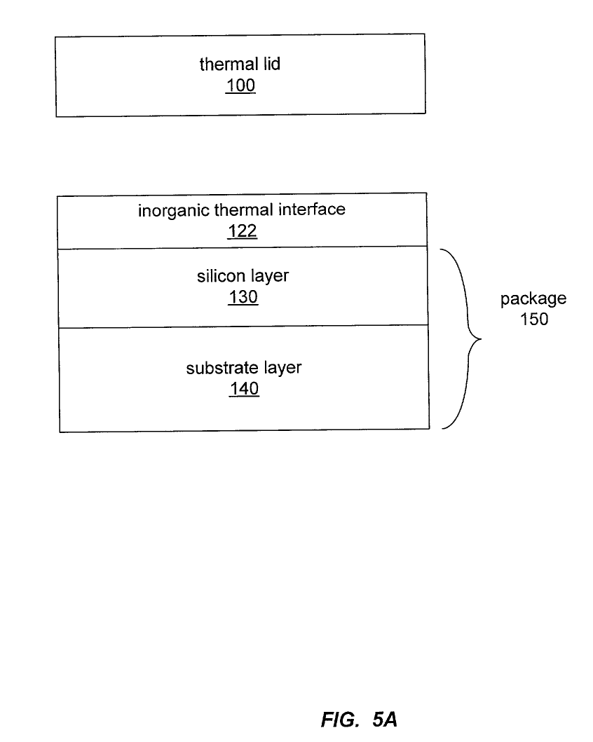

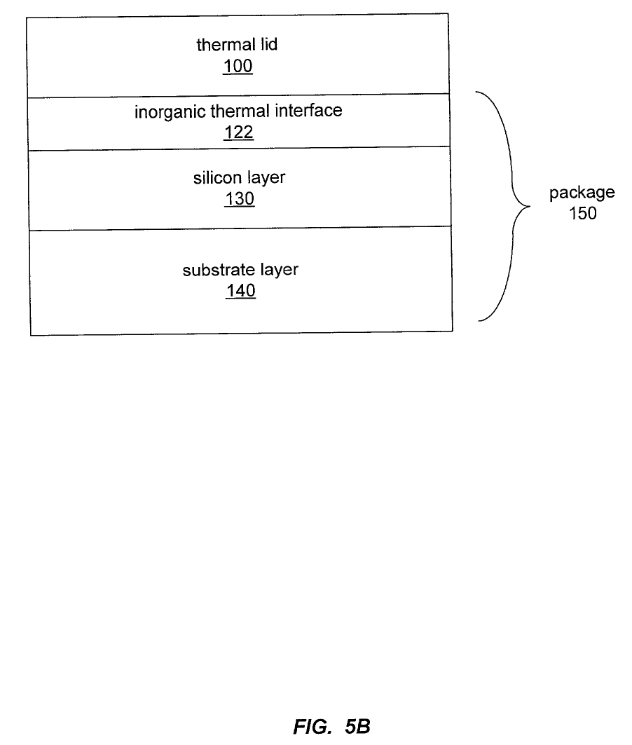

FIG. 5A depicts placing inorganic thermal interface 122 on silicon layer 130. FIG. 5A depicts silicon layer 130 and substrate layer 140 which combine to form package 150. FIG. 5B depicts placement of thermal lid 110 on silicon layer 130. Substrate layer 140 is bonded to the opposing side of silicon layer 130 from inorganic thermal interface 121 and thermal lid 100.

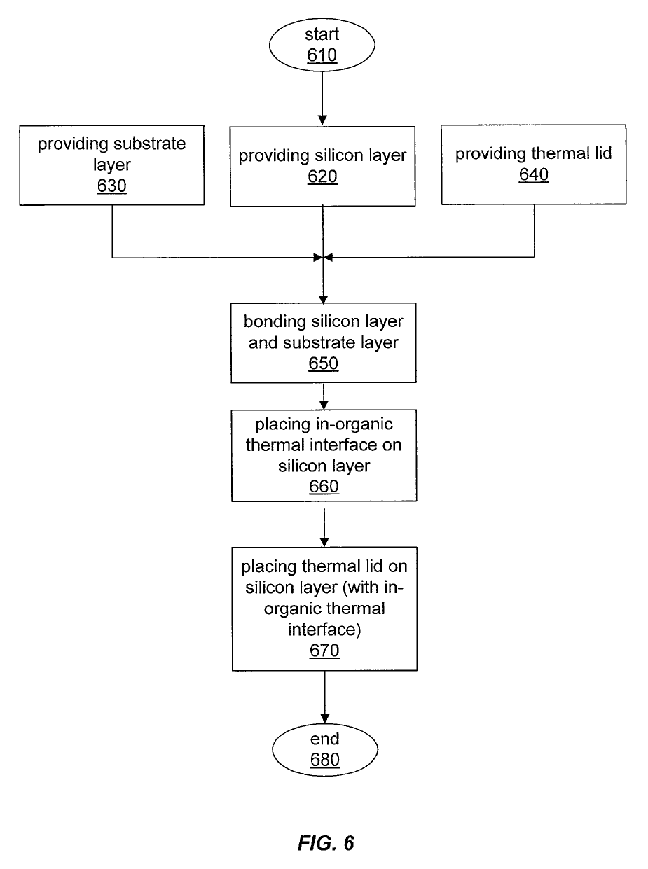

FIG. 6 depicts the logical steps of placing inorganic organic thermal interface 422 on the silicon layer. As shown in FIG. 6, the method begins with start 410. From start 410 the logical steps include providing substrate layer 430, providing silicon layer 420 and providing thermal lid 440. After providing silicon layer 420 and providing substrate layer 430 the silicon layer and substrate layer are bonded 450. Providing thermal lid 440 is shown occurring prior to bonding the silicon layer to the substrate layer 450 but in an implementation can occur later. After providing thermal lid 440 the inorganic thermal interface is placed on the silicon layer 460. After the inorganic thermal interface is placed on the silicon layer 460 the thermal lid is placed on the silicon layer 470. After the thermal lid and organic thermal interface are placed on the silicon layer 470, the process ends 480.

Integrated circuit chips formed by the method described above can be used in many electronic devices including televisions, radios, automobiles, data processing systems and computers systems. In a computer system the integrated circuit can be a central processing unit (cpu), memory or serve another function. A block diagram of an example of a computer system is shown below.

An Example of a Computer System

The present disclosure is applicable to any integrated circuit including data processing systems. Integrated circuits may be found in many components of a typical computer system, for example a central processing unit, memory, cache, audio controller, network interface, I/O controller and I/O device as shown in the example below. Integrated circuits are found in other components within a computer system such as a display monitor, keyboard, floppy and hard disk drive, DVD drive, CD-ROM and printer. However, the example of a computer system is not taken to be limiting. Integrated circuits are ubiquitous and are found in other electrical systems such as stereo systems and mechanical systems including automobiles and aircraft.

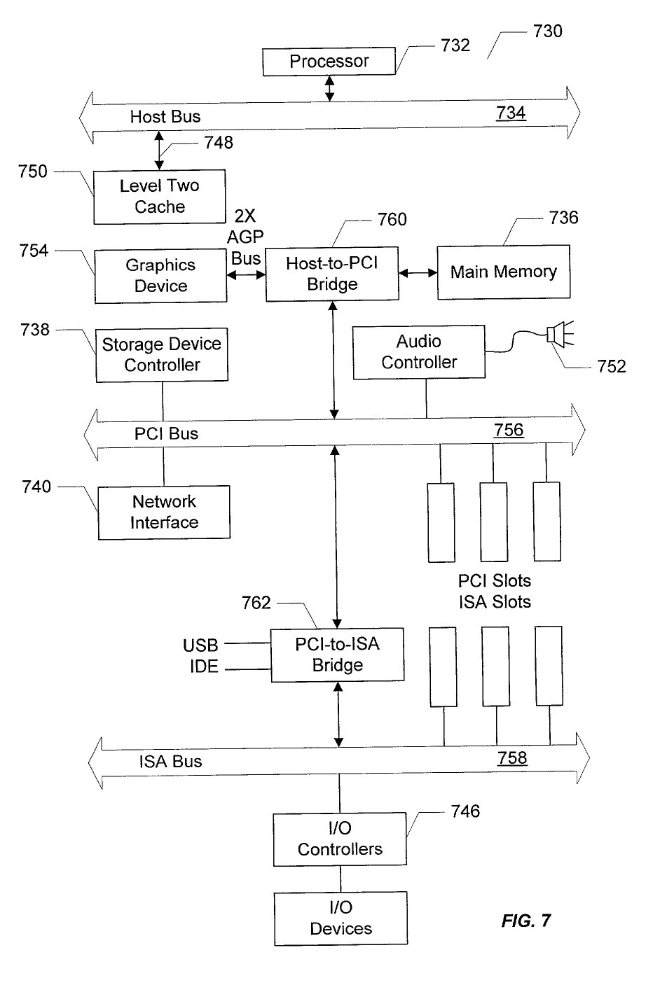

Referring to FIG. 7, computer system 730 includes central processing unit (CPU) 732 connected by host buss 734 to various components including main memory 736, storage device controller 738, network interface 740, audio and video controllers 742, and input/output devices 744 connected via input/output (I/O) controllers 746.

Typically computer system 730 also includes cache memory 750 to facilitate quicker access between processor 732 and main memory 736. I/O peripheral devices often include speaker systems 752, graphics devices 754, and other I/O devices 744 such as display monitors, keyboards, mouse-type input devices, floppy and hard disk drives, DVD drives, CD-ROM drives, and printers. Many computer systems also include network capability, terminal devices, modems, televisions, sound devices, voice recognition devices, electronic pen devices, and mass storage devices such as tape drives. The number of devices available to add to personal computer systems continues to grow, however computer system 630 may include fewer components than shown in FIG. 7 and described herein. The peripheral devices usually communicate with processor 732 over one or more buses 734, 756, 758, with the buses communicating with each other through the use of one or more bridges 760, 762.

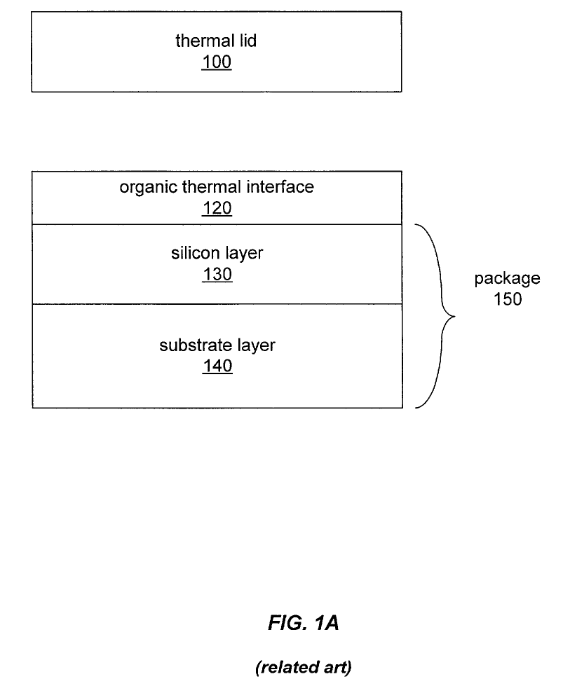

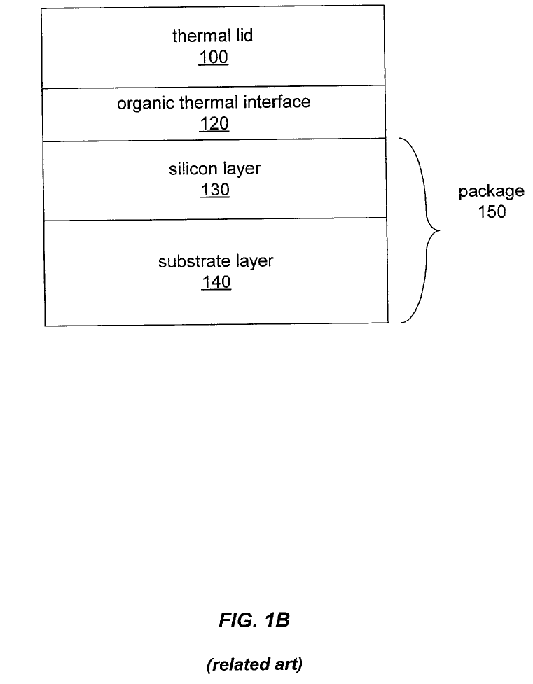

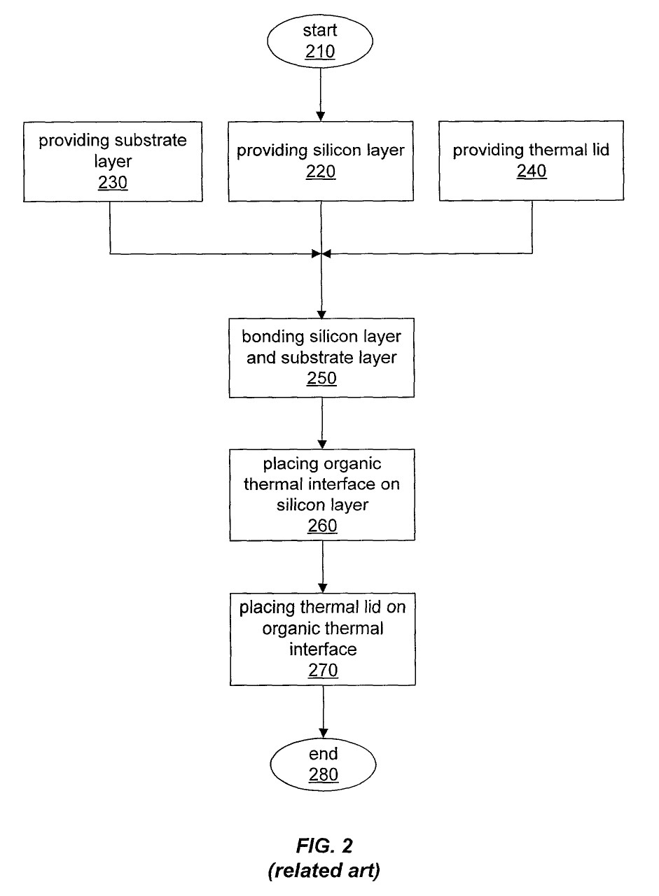

Those of skill in the art will recognize that, based upon the teachings herein, several modifications may be made to the embodiments shown in FIGS. 1-7. For example, those skilled in the art will recognize that incorporating integrated circuits manufactured by the process shown in electrical systems other than computers systems is incorporated in the spirit and scope of the invention.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

What is claimed is:

1. A method of facilitating heat transfer from a silicon layer during manufacture of an integrated circuit package, comprising:
providing a silicon layer;
providing a substrate layer;
bonding the silicon layer to the substrate layer;
providing a thermally conductive lid;
providing a thermal interface;
operably disposing the thermal interface on the thermal lid; and
placing the thermally conductive lid on the silicon layer.

2. The method as recited in claim 1, wherein the step of providing the thermal interface provides the thermal interface having a melting point above 16° C.

3. The method as recited in claim 1, wherein the step of providing the thermal interface provides the thermal interface having a melting point above 62° C.

4. The method as recited in claim 1, wherein the step of providing the thermal interface provides the thermal interface having a melting point above 16° C. and below 105° C.

5. The method as recited in claim 1, wherein the step of providing the thermal interface provides T-lma-60.

6. The method as recited in claim 1, wherein the step of providing the thermal interface provides an alloy.

7. The method as recited in claim 1, wherein the step of providing the thermal interface provides a thermal interface comprising:
tin; and
lead.

8. The method as recited in claim 1, wherein the step of providing the thermal interface provides a metal.

9. A method of facilitating heat transfer from a silicon layer during manufacture of an integrated circuit package, comprising:
providing a silicon layer;
providing a substrate layer;
bonding the silicon layer to the substrate layer;
providing a thermally conductive lid;
providing a non-organic thermal interface.
operably disposing the non-organic thermal interface on the silicon layer; and
placing the thermally conductive lid on the silicon layer.

10. The method as recited in claim 9, wherein the step of providing the thermal interface provides the thermal interface having a melting point above 16° C.

11. The method as recited in claim 9, wherein the step of providing the thermal interface provides the thermal interface having a melting point above 62° C.

12. The method as recited in claim 9, wherein the step of providing the thermal interface provides the thermal interface having a melting point above 16° C. and below 105° C.

13. The method as recited in claim 9, wherein step of providing the thermal interface provides an alloy.

14. The method as recited in claim 9, wherein the step of providing a thermal interface provides an alloy, the alloy comprising:
tin; and
lead.

15. The method as recited in claim 9, wherein the step of providing a thermal interface provides a metal.

16. An integrated circuit package manufactured by a method, comprising:
providing a silicon layer;
providing a substrate layer;
bonding the silicon layer to the substrate layer;
providing a thermal lid;
providing a thermal interface;
operably disposing the thermal interface on the thermal lid; and
placing the thermally conductive lid on the silicon layer.

17. The method as recited in claim 16, wherein the step of providing the thermal interface provides the thermal interface having a melting point above 16° C.

18. The method as recited in claim 16, wherein the step of providing the thermal interface provides the thermal interface having a melting point above 62° C.

19. The method as recited in claim 16, wherein the step of providing the thermal interface provides the thermal interface having a melting point above 16° C. and below 105° C.

20. The integrated circuit package as recited in claim 16, wherein the step of providing a thermal interface provides an alloy.

21. The integrated circuit as recited in claim 16, wherein the step of providing a thermal interface provides a metal.

22. The integrated circuit as recited in claim 16, wherein the step of providing a thermal interface provides T-lma-60.

23. The integrated circuit package as recited in claim 16, wherein the step of providing a thermal interface provides an alloy, the alloy comprising:
tin; and
lead.

24. An integrated circuit package manufactured by a method, comprising:
providing a silicon layer;
providing a substrate layer;
bonding the silicon layer to the substrate layer;
providing a thermal lid;
providing a non-organic thermal interface;
operably disposing the non-organic thermal interface on the silicon layer; and
placing the thermally conductive lid on the non-organic thermal interface,
wherein the non-organic thermal interface is operably disposed on the silicon layer.

25. The method as recited in claim 24, wherein the step of providing the thermal interface provides the thermal interface having a melting point above 16° C.

26. The method as recited in claim 24, wherein the step of providing the thermal interface provides the thermal interface having a melting point above 62° C.

27. The method as recited in claim 24, wherein the step of providing the thermal interface provides the thermal interface having a melting point above 16° C. and below 105° C.

28. The integrated circuit as recited in claim 24, wherein step of providing the thermal interface provides:
tin; and
lead.

29. The integrated circuit as recited in claim 24, wherein the step or providing the thermal interface provides a metal.

30. The integrated circuit as recited in claim 24, wherein the step of providing the thermal interface provides an alloy.

31. A computer system, comprising:
a memory,
a central processing unit, the central processing unit manufactured by a method comprising:
providing a silicon layer;
providing a substrate layer;
bonding the silicon layer to the substrate layer;
providing a thermal lid;
providing a thermal interface;
operably disposing the thermal interface on the thermal lid; and
placing the thermally conductive lid on the silicon layer.

32. The method as recited in claim 31, wherein the step of providing the thermal interface provides the thermal interface having a melting point above 16° C.

33. The method as recited in claim 31, wherein the step of providing the thermal interface provides the thermal interface having a melting point above 62° C.

34. The method as recited in claim 31, wherein the step of providing the thermal interface provides the thermal interface having a melting point above 16° C. and below 105° C.

35. The integrated circuit as recited in claim 31, wherein the step of providing a thermal interface provides an alloy.

36. The integrated circuit as recited in claim 31, wherein the step of providing a thermal interface provides a metal.

37. The integrated circuit as recited in claim 31, wherein the step of providing the thermal interface provides T-lma-60.

38. The integrated circuit as recited in claim 31, wherein the step of providing the thermal interface provides an alloy.

39. The integrated circuit as recited in claim 31, wherein the step of providing the thermal interface provides an alloy, the allow comprising:
tin; and
lead.

40. A computer system, comprising:
a central processing unit; and
a memory, the memory manufactured by a method comprising:
providing a silicon layer;
providing a substrate layer;
bonding the silicon layer to the substrate layer;
providing a thermal lid;
providing a non-organic thermal interface;
operably disposing the non-organic thermal interface on the silicon layer; and
placing the thermally conductive lid on the non-organic thermal interface, wherein the non-organic thermal interface is operably disposed on the silicon layer.

41. The method as recited in claim 40, wherein the step of providing the thermal interface provides the thermal interface having a melting point above 16° C.

42. The method as recited in claim 40, wherein the step of providing the thermal interface provides the thermal interface having a melting point above 62° C.

43. The method as recited in claim 40, wherein the step of providing the thermal interface provides the thermal interface having a melting point above 16° C. and below 105° C.

44. The integrated circuit as recited in claim 40, wherein the step of providing the thermal interface provides an alloy.

45. The integrated circuit as recited in claim 40, wherein the step of providing the thermal interface provides a metal.

46. The integrated circuit as recited in claim 40, wherein the step of providing the thermal interface provides an alloy, the alloy comprising:
tin; and
lead.
